(19) United States
(12) Patent Application Publication
(10) Pub. No.: US 2009/0001576 A1
(43) Pub. Date: Jan. 1, 2009

(54) INTERCONNECT USING LIQUID METAL

(76) Inventors: Surinder Tuli, Scottsdale, AZ (US); Wayne Mulholland, Gilbert, AZ (US); Song-Hua Shi, Chandler, AZ (US); Ioan Sauciuc, Phoenix, AZ (US); Patricia Brusso, Chandler, AZ (US); Jacinta Aman Lim, Maricopa, AZ (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/771,909

(22) Filed: Jun. 29, 2007

(51) Int. Cl. H01L 23/52; H01L 21/60

(52) U.S. Cl. 257/750; 438/106; 257/E23.141; 257/E21.506

(57) ABSTRACT

A semiconductor package comprises a substrate that has a first protruding interconnect and a semiconductor die that has a second protruding interconnect that faces the first protruding interconnect. The package further comprises a spacer provided between the substrate and the die, wherein the spacer comprises a hole filled with liquid metal to couple the first protruding interconnect to the second protruding interconnect.

### BACKGROUND

Reflow process may bring some issues such as Interlayer Dielectric (ILD) cracking, solder joint cracking after first level and second level interconnection or during reliability tests, and non-reworkability. Die build up structure optimization technology may be used to reduce ILD cracking. First level or second level adhesive technologies may reduce solder joint cracking. However, methods to improve reworkability are lacking for underfill first level and second level assemblies.

### BRIEF DESCRIPTION OF THE DRAWINGS

The invention described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIG. 1 is a schematic diagram of an embodiment of a package that may comprise a spacer to couple a die to a substrate.

FIG. 2 is a schematic diagram of another embodiment of a package that may comprise a spacer to couple a die to a substrate.

FIG. 3 is a schematic diagram of yet another embodiment of a package that may comprise a spacer to couple a substrate of the package to a motherboard.

FIG. 4 is a flow chart of a method that may be used to provide the package of FIG. 3.

### DETAILED DESCRIPTION

In the following detailed description, references are made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numbers refer to the same or similar functionality throughout the several views.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

The following description may include terms, such as upper, lower, top, bottom, first, second, etc. that are used for descriptive purposes only and are not to be construed as limiting.

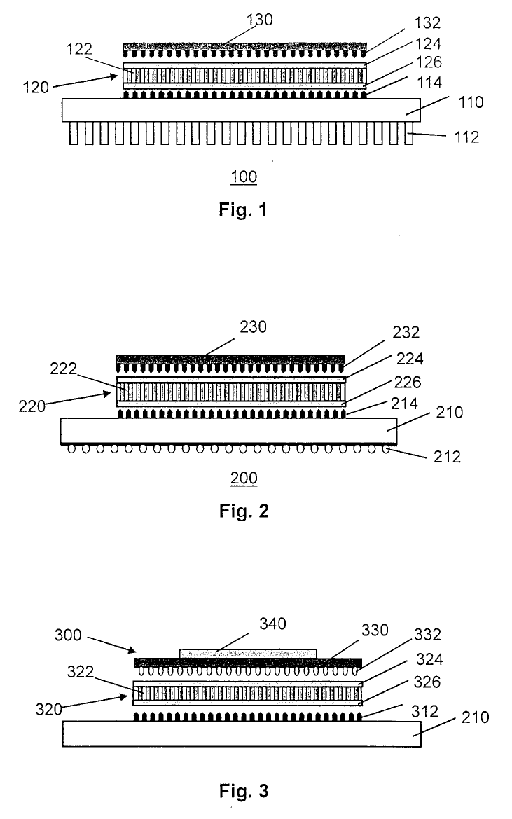

FIG. 1 illustrates an exemplary embodiment of a semiconductor package 100. In one embodiment, the package 100 may comprise a substrate 110. For example, the substrate 110 may comprise a pin grid array (PGA) substrate that may comprise a set of one or more pins 112 on a lower side of the substrate 110, e.g., to couple the substrate 110 to a mother board (not shown); however, in some embodiments, other external interconnects such as solder balls may be utilized. In another embodiment, the substrate 110 may comprise a first set of one or more bumps 114 that may be provided on an upper side of the substrate 110; however, in some embodiments, any other protruding interconnects 114 such as gold stud bump or conductive protrusions may be utilized. One example of the substrate 110 may comprise a printed circuit board (PCB) or a printed wiring board (PWB); however, any other suitable substrate may be utilized, including flex substrates such as folded flex substrates or flexible polyimide tape, laminate substrates, buildup substrates, ceramic substrates, flame retardant (FR-4) substrate, or tape automated bonding (TAB) tape material.

Referring to FIG. 1, in one embodiment, the package 100 may comprise a spacer 120 that may be provided between the substrate 110 and a die 130. In one embodiment, the die 130 may be provided on the spacer 120 and may comprise a second set of one or more bumps 132; however, in some embodiments, the die 130 may comprise any other protruding interconnects, such as gold stud bumps or conductive protrusions. In one embodiment, the second set of bumps 132 faces the first set of bumps 114. In another embodiment, an example of the die 130 may comprise a bump die. While FIG. 1 illustrates a die on the substrate 110, in some embodiments, more dies may be provided on the substrate 110.

With reference to FIG. 1, the spacer 120 may be patterned to comprise a set of one or more holes 122. The set of holes 122 may be arranged to match an arrangement of the first set of bumps 114 and an arrangement of the second set of bumps 132. A hole 122 may be patterned to match a pattern of a bump 114 and a pattern of a bump 132. In one embodiment, a hole 122 may be filled with liquid metal, such as an alloy that may comprise Gallium and Indium. Example of the liquid metal may comprise 61.0Ga/25.0In/13.0Sn/1.0Zn, 62.5Ga/21.5In/16.0Sn, 75.5Ga/24.5In, 95Ga/5In or any other materials that may comprise Gallium and Indium; however, any other liquid conductive materials may be utilized. In another embodiment, an example of material for the spacer 120 may comprise polymeric materials, such as Teflon, silicone, or polyimide materials.

In one embodiment, the spacer 120 may comprise an upper sealing film 124 on an upper side of the spacer 120 and a lower sealing film 126 on a lower side of the spacer 120 to seal the liquid metal in the holes 122. Example material for the upper sealing film 124 and the lower sealing film 126 may comprise polymer such as polyimide or silicone materials. In another embodiment, the upper sealing film 124 and/or the lower sealing film 126 may comprise a sticky tape. In one embodiment, the upper sealing film 124 and the lower sealing film 126 may be attached or stuck to the spacer 120 to improve sealing strength and prevent liquid metal leakage. In another embodiment, the set of holes 122 may be arranged to match an arrangement of the first set of bumps 114 on the substrate 110 and/or an arrangement of the second set of bumps 132 on the die 130. In one embodiment, the upper sealing film 124 may comprise an adhesive on an upper surface. In another embodiment, the upper sealing film 124 may comprise a tacky upper surface. In yet another embodiment, the lower sealing film 126 may comprise an adhesive on a lower surface. In another embodiment, the lower sealing film 126 may comprise a tacky lower surface.

In one embodiment, the spacer 120 may be aligned with the die 130 and the substrate 110, so that a hole 122 may be aligned with one of a first set of bumps 114 and one of a second set of bumps 132. The die 130 may be coupled with the substrate 110 by the spacer 120. For example, a retention mechanism (not shown) such as a clamp may be used to couple the die 130 with the substrate 110. A bump 132 on the die 130 may pierce the upper sealing film 124 to contact the liquid metal filled in a hole 122 and a bump 114 on the substrate 110 may pierce the lower sealing film 126 to contact the liquid metal in the hole 122, so that the liquid metal may provide an electrical path for the package 100 to interconnect the bump 132 on top of the hole 122 and the bump 114 on a lower side of the hole 122. The die 130 may be coupled to the substrate 110 by the liquid metal in a hole 122 that may interconnect a bump 132 and a bump 114.

In one embodiment, the upper sealing film 124 may have a thickness that may allow the upper sealing film 124 to be pierced by a bump 132 of the die 130, e.g., from about 1 um to about 20 um. In another embodiment, the lower sealing film 126 may have a thickness that may allow the lower sealing film 126 to be pierced by a bump 114 of the substrate 110, e.g., from about 1 um to about 20 um. In another embodiment, the spacer 120 may have a thickness that may match a height of a bump 132 of the die 130 plus a height of a bump 114 of the substrate 110. For example, the thickness of the spacer 120 may be from about 5 um to about 1000 um. In another embodiment, the upper sealing film 124 may comprise a first set of openings (not shown) that may each correspond to a hole 122 and may ease the piercing of a bump 132. Similarly, the lower sealing film 126 may comprise a second set of openings (not shown) that may each correspond to a hole 122 and may ease the piercing of a bump 114.

FIG. 2 illustrates an exemplary embodiment of a semiconductor package 200. Referring to FIG. 2, the package 200 may comprise a spacer 220 that may couple a die 230 to a substrate 210. In one embodiment, the substrate 210 may be a ball grid array (BGA) substrate that may comprise a set of one or more solder balls 212 on one side, e.g., the lower side of FIG. 2; however, in some embodiments, any other external interconnects may be utilized. In another embodiment, the substrate 210 may further comprise a first set of protruding interconnects such as bumps 214 on the upper side that may be coupled to the die 230. Examples of the substrate 210 may refer to the corresponding description with regard to the substrate 110 of FIG. 1.

The spacer 220 may be provided on the substrate 210 and may comprise a set of one or more holes 222 that may each be filled with liquid metal. The spacer 220 may comprise an upper sealing film 224 and a lower sealing film 226 that may seal the liquid metal in a hole 222. More description on the spacer 220 may be referred to the corresponding description on the spacer 120 of FIG. 1 and thus is omitted herein. The die 230 may be provided on the spacer 220 and may be a bump die that may comprise a second set of one or more bumps 232 on the lower side; however, in some embodiments, any other protruding interconnects may be utilized. Similar to the package 100 of FIG. 1, the die 230, the spacer 220 and the substrate 210 may be aligned and the die 230 may be coupled with the substrate 210 by the spacer 220. In one embodiment, a bump 232 that is aligned with a hole 222 may pierce the upper sealing film 224 to insert into the hole 222 and a bump 214 that is aligned with the hole 222 may pierce the lower sealing film 226 to insert into the hole 222. The die 230 may be coupled to the substrate 210 by the liquid metal filled in a hole 222 that may interconnect a bump 232 of the die 230 and a bump 214 of the substrate 210.

In one embodiment, the upper sealing film 224 may comprise a tacky upper surface to facilitate an attachment between the die 230 and the spacer 220. In another embodiment, the lower sealing film 226 may comprise a tacky lower surface. In yet another embodiment, an upper surface of the upper sealing film 224 and/or a lower surface of the lower sealing film 226 may comprise an adhesive.

FIG. 3 illustrates another embodiment of a semiconductor package 300. In one embodiment, the package 300 may be provided on a motherboard 310. The motherboard 310 may comprise a first set of one or more bumps 312, e.g., on an upper side; however, in some embodiments, any other protruding interconnects may be utilized. In another embodiment, the package 300 may comprise a substrate 330 that may be provided on a spacer 320. The substrate 330 may comprise a second set of one or more protruding interconnects such as bumps 332 on a lower side. An example of the substrate 330 may comprise a flip chip (FC) substrate. A die 340 may be provided or mounted on the substrate 330. In one embodiment, the die 340 may be coupled to the substrate 330.

Referring to FIG. 3, a spacer 320 may be provided between the package 300 and the motherboard 310. The description of the spacer 320 may refer to the corresponding description on the spacer 120 of FIG. 1 or the spacer 220. For example, the spacer 320 may comprise a set of one or more holes 322 that may each be filled with a metal that may be in a liquid state, e.g., at a room temperature. The spacer 320 may further comprise an upper sealing film 324 and a lower sealing film 326 to seal the metal in a hole 322.

The package 300, the spacer 320 and the motherboard 310 may be aligned and the substrate 330 may be coupled with the motherboard 310 by the spacer 320. For example, the substrate 330 and the motherboard 310 may be clamped. A bump 332 on the substrate 330 may pierce the upper sealing film 324 to couple to the metal in a hole 322 that is aligned with the bump 332 and may be coupled to a corresponding bump 312 that may pierce the lower sealing film 324 to couple to the metal in the hole 322. Thus, the spacer 320 may provide an electrical path for the package 300 to interconnect the substrate 330 and the motherboard 310 by the metal filled in a hole 322.

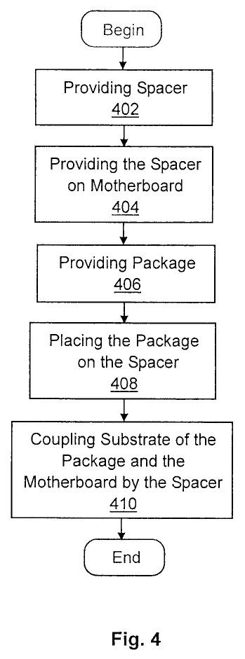

FIG. 4 illustrates an exemplary embodiment of a method that may be used to provide the semiconductor package 300 of FIG. 3. In block 402, the spacer 320 may be provided. The spacer 320 may be patterned to comprise the set of holes 322. In one embodiment, a hole 322 may be patterned to have a size that may match a size of a bump 312 of the motherboard 310 and a size of a bump 332 of the substrate 330. In another embodiment, the set of holes 322 may be arranged to match the arrangement of the first set of bumps 312 and the arrangement of the second set of bumps 332. In yet another embodiment, a hole 322 may have a shape that matches a shape of the bump 312 and a shape of the bump 332.

Referring to FIGS. 3 and 4, the lower sealing film 326 may be attached to the lower side of the spacer 320. In one embodiment, an adhesive such as epoxy resin may be used to attach the lower sealing film 326 to the spacer 320. In another embodiment, the lower sealing film 326 may comprise an adhesive surface or an adhesive film on a top side to attach the lower sealing film 326 to the spacer 320 and prevent liquid metal leakage. In another embodiment, the lower sealing film 326 may comprise a tacky top surface. A hole 322 of the spacer 320 may be filled with liquid metal such as Gallium Indium alloy. The upper sealing film 324 may be attached to the upper side of the spacer 320 to seal the liquid metal in a hole 322. In one embodiment, the upper sealing film 324 may be attached to the spacer 320 in a manner similar to that is used to attach the lower sealing film 326. In another embodiment, the upper sealing film 326 may comprise an adhesive on a lower side. In another embodiment, the upper sealing film 326 may comprise a tacky lower surface. In yet another embodiment, the upper sealing film 324 and/or the lower sealing film may comprise a sticky tape.

Referring to FIGS. 3 and 4, the spacer 320 may be provided on the motherboard 310 (block 404). In one embodiment, the spacer 320 may be aligned with the motherboard 310, so that a hole 322 of the spacer 320 may be aligned with a bump 312 of the motherboard 310. In block 406, the die 340 may be attached and coupled to the substrate 330, e.g., an upper side, to provide the package 300. In one embodiment, the second set of bumps 332 may be formed on the other side of the substrate 330. In block 408, the package 300 may be provided on the spacer 320. In one embodiment, the package 300 and/or the substrate 330 may be aligned with the spacer 320 to align a bump 332 with a hole 322 of the spacer 320.

Referring to FIG. 4, in block 410, the substrate 330 may be coupled with the motherboard 310 by the spacer 320, e.g., at a room temperature. For example, the motherboard 310 and the substrate 330 may be clamped. In one embodiment, a clamping mechanism may be utilized. A bump 332 of the substrate 330 may pierce the upper sealing film 324 and insert into a corresponding hole 322 to contact the metal in the hole 322. Similarly, a bump 312 of the motherboard 310 that aligns with the bump 332 may pierce the lower sealing film 326 and insert into the hole 322 to contact the metal in the hole 322. In another embodiment, the motherboard 310 may be held or fixed and the substrate 330 may be pressed downward to interconnect the substrate 330 and the motherboard 310. In yet another embodiment, the motherboard 310 and the substrate 330 may be pressed together to couple the motherboard 310 with the substrate 330. In one embodiment, the upper sealing film 124 may comprise an adhesive on an upper surface. In another embodiment, the upper sealing film 124 may comprise a tacky upper surface. In yet another embodiment, the lower sealing film 126 may comprise an adhesive on a lower surface. In another embodiment, the lower sealing film 126 may comprise a tacky lower surface.

While each of FIG. 1-3 illustrates a spacer that may comprise an upper sealing film and a lower sealing film, in some embodiments, the upper sealing film may not be required. While the method of FIG. 4 is illustrated to comprise a sequence of processes, the method in some embodiments may perform illustrated processes in a different order. For example, the substrate 330 may be provided on the spacer 320 prior to the die 340 being attached to the substrate 330. In another embodiment, the method of FIG. 4 may be modified to provide the package 100 of FIG. 1. For example, in order to provide the package 100, block 404 may be modified to provide the spacer 120 on the substrate 110, block 406 may be modified to provide the die 130 on the spacer 120, and block 408 may be omitted. In another embodiment, FIG. 4 may be modified similarly to provide the package 200 of FIG. 2.

While certain features of the invention have been described with reference to embodiments, the description is not intended to be construed in a limiting sense. Various modifications of the embodiments, as well as other embodiments of the invention, which are apparent to persons skilled in the art to which the invention pertains are deemed to lie within the spirit and scope of the invention.

What is claimed is:

1. A semiconductor package, comprising:
a substrate that has a first protruding interconnect;
a semiconductor die that has a second protruding interconnect that faces the first protruding interconnect; and
a spacer provided between the substrate and the die, wherein the spacer comprises a hole filled with liquid metal to couple the first protruding interconnect to the second protruding interconnect.

2. The package of claim 1, wherein the spacer comprises a first sealing film to seal the liquid metal in the hole, wherein the first protruding interconnect pierces the first sealing film to contact the liquid metal.

3. The package of claim 1, wherein the spacer comprises a second sealing film to seal the liquid metal in the hole, wherein the second protruding interconnect pierces the second sealing film to contact the liquid metal.

4. The package of claim 1, wherein the first protruding interconnect, the hole and the second protruding interconnect are aligned.

5. The package of claim 1, wherein each of the first protruding interconnect and the second protruding interconnect comprises one selected from a group that comprises a bump and a conductive protrusion.

6. The package of claim 1, wherein the liquid metal comprises one from a group comprising 61.0Ga/25.0In/13.0Sn/0.1Zn, 62.5Ga/21.5In/16.0Sn, 75.5Ga/24.5In, and 95Ga/5In.

7. The package of claim 1, wherein the spacer comprises one from a group comprising Teflon, silicone, and polyimide materials.

8. The package of claim 2, wherein the first sealing film comprises one from a group comprising polyimide and silicone material.

9. A method, comprising:
providing a spacer between a substrate of a semiconductor package and a motherboard, wherein the substrate has a first protruding interconnect and the motherboard has a second protruding interconnect that faces the first protruding interconnect, and wherein the spacer comprises a hole filled with liquid metal; and
coupling the substrate and the motherboard by the spacer.

10. The method of claim 9, comprising:
attaching a first sealing film to a side of the spacer to seal the liquid metal in the hole, and
piercing the first sealing film by the first protruding interconnect.

11. The method of claim 9, comprising:
attaching a second sealing film to a side of the spacer to seal the liquid metal in the hole, and
piercing the second sealing film by the second protruding interconnect.

12. The method of claim 9, comprising:
aligning the first protruding interconnect, the hole and the second protruding interconnect.

13. The method of claim 9, comprising:
patterning the spacer to provide the hole.

14. The method of claim 9, comprising:
clamping the substrate and the motherboard to couple the first protruding interconnect to the second protruding interconnect by the liquid metal.

15. The method of claim 9, wherein each of the first protruding interconnect and the second protruding interconnect comprises one selected from a group that comprises a bump and a conductive protrusion.
